(19) United States
(12) Patent Application Publication
(10) Pub. No.: US 2024/0357900 A1
(43) Pub. Date: Oct. 24, 2024

(54) ELASTIC MEMBER AND DISPLAY DEVICE COMPRISING SAME

(71) Applicant: LG INNOTEK CO., LTD., Seoul (KR)

(72) Inventors: Sang Jun KO, Seoul (KR); Sung Won KANG, Seoul (KR); Jung Min GWAK, Seoul (KR)

(21) Appl. No.: 18/685,636

(22) PCT Filed: Aug. 26, 2022
(86) PCT No.: PCT/KR2022/012824

§ 371 Date: Feb. 22, 2024

(30) Foreign Application Priority Data
Aug. 27, 2021 (KR) 10-2021-0114286

(51) Int. Cl. H10K 59/80; B32B 3/26; B32B 7/12; B32B 15/04; H10K 102/00

(52) U.S. Cl. CPC H10K 59/80; B32B 3/266; B32B 15/04; B32B 7/12; B32B 2307/7376; B32B 2457/206; H10K 2102/311

(57) ABSTRACT

An elastic member according to an embodiment includes: a first region and a second region, wherein a first direction defined as a width direction and a second direction defined as a longitudinal direction in the elastic member, the first region is defined as a folding region that is folded with the first direction as a folding axis, the second region is defined as an unfolding region, a width of the first region is smaller than a width of the second region, and the width of the first region is 15 mm or more.

### TECHNICAL FIELD

Embodiments relate to an elastic member and a display device including the same.

### BACKGROUND

Recently, there is an increasing demand for a flexible or foldable display device capable of easily carrying various applications and displaying an image on a large screen when being carried.

Such a flexible or foldable display device is folded or partially bent when being carried or stored, and may be implemented with the display unfolded when displaying images. Accordingly, an image display region may be increased, and a user may easily carry the display.

After the flexible or foldable display device is folded or bent, a restoration process of unfolding the flexible display device again may be repeated.

That is, since the flexible or foldable display device repeats folding and unfolding operations, a substrate of the flexible display device is repeatedly used, so that flatness may be deteriorated.

In detail, in the flexible or foldable display device, since a folding region is a region where stress is concentrated during repeated folding and unfolding, the flatness may be deteriorated compared with unfolding region.

Accordingly, there is a problem that cracks occur in the folding region or wrinkles visually recognized from the outside occur, and thus the lifespan of the flexible or foldable display device is reduced and the reliability is deteriorated.

Therefore, there is a need for an elastic member having a new structure capable of solving the above problems.

### SUMMARY

### Technical Problem

An embodiment is directed to providing an elastic member capable of having a low flatness even when folding and restoring are repeated and a display device including the same.

### Technical Solution

An elastic member according to an embodiment includes: a first region and a second region, wherein a first direction defined as a width direction and a second direction defined as a longitudinal direction in the elastic member, the first region is defined as a folding region that is folded with the first direction as a folding axis, the second region is defined as an unfolding region, a width of the first region is smaller than a width of the second region, and the width of the first region is 15 mm or more.

### Advantageous Effects

In an elastic member according to an embodiment, a width of the folding region in which the elastic member is folded has a set size. Accordingly, a magnitude of flatness of the elastic member may be reduced. Accordingly, it is possible to prevent a shape of the folding region of the elastic member from being changed even when folding and restoring are repeated. In addition, it is possible to prevent cracks from occurring in the folding region by increasing the flatness of the elastic member.

That is, in the elastic member according to the embodiment, the width of the folding region may be formed in 15 mm or more. Accordingly, compressive stress and tensile stress generated in the folding region due to folding and restoring are distributed over a large area. Accordingly, it is possible to prevent stress from being concentrated in a specific region of the elastic member. In addition, it is possible to reduce stress per unit area of the folding region.

Accordingly. It is possible to reduce the magnitude of the flatness that is increased by increasing the magnitude of the stress. Therefore, it is possible to increase the lifespan of the elastic member, and to prevent the folding reliability from being deteriorated due to deformation of the folding region.

### BRIEF DESCRIPTION OF THE DRAWINGS

FIG. 1 is a perspective view of a display device according to an embodiment.

FIG. 2 is a perspective view of an elastic member according to an embodiment.

FIG. 3 is a side view of the elastic member according to the embodiment before folding.

FIG. 4 is a side view of the elastic member according to the embodiment after folding.

FIG. 5 is a top view of the elastic member according to the embodiment.

FIG. 6 is another top view of the elastic member according to the embodiment.

FIGS. 7 to 11 are views for describing flatness of the elastic member according to the embodiment.

FIGS. 12 and 13 are graphs illustrating flatness of elastic members according to Examples and Comparative Examples.

FIGS. 14 to 16 are cross-sectional views for describing a layer structure of the elastic member according to the embodiment.

FIGS. 17 and 18 are cross-sectional views for describing an arrangement structure of the elastic member according to the embodiment.

FIGS. 19 to 20 are cross-sectional views of a flexible support including the elastic member according to the embodiment.

FIGS. 21 and 22 are cross-sectional views of a display device including the flexible support according to the embodiment.

FIG. 23 is a view for describing an example in which the display device according to the embodiment is applied.

### DETAILED DESCRIPTION OF THE EMBODIMENTS

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and replaced. In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art.

In addition, the terms used in the embodiments of the present disclosure are for describing the embodiments and are not intended to limit the present disclosure. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected” or “coupled” to another element, it may include not only when the element is directly “connected” or “coupled” to other elements, but also when the element is “connected” or “coupled” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

Hereinafter, an elastic member according to an embodiment and a folding support and a display device including the same will be described with reference to the drawings.

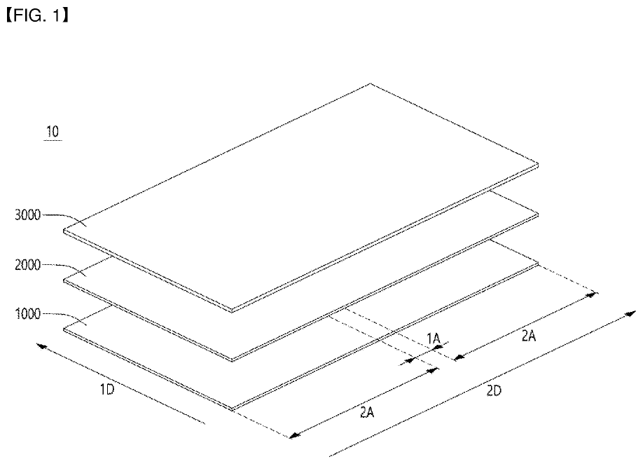

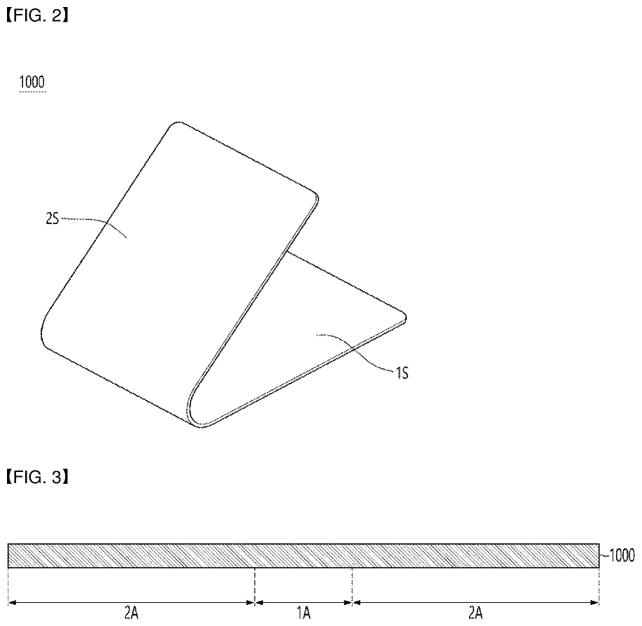

FIG. 1 is a perspective view of a display device according to an embodiment, and FIGS. 2 to 4 are perspective views and cross-sectional views of an elastic member of the display device according to the embodiment.

Referring to FIG. 1, a display device 10 according to the embodiment includes an elastic member 1000 and a panel disposed on the elastic member 1000. The panel may include at least one of a display panel 2000 and a touch panel 3000.

The elastic member 1000 may support the display panel 2000 and the touch panel 3000. That is, the elastic member 1000 may be a support substrate supporting the display panel 2000 and the touch panel 3000.

Meanwhile, the touch panel 3000 may be integrally formed with the display panel 2000. For example, the touch panel 3000 may be integrally formed with the display panel 2000 in an on-cell or in-cell method.

The elastic member 1000 may include a metallic material and a non-metallic material. In detail, the elastic member 1000 may be formed of a plurality of layers. In addition, the plurality of layers may include at least one of the metallic material and the non-metallic material. For example, the elastic member 1000 may include metal, metal alloy, plastic, a composite material (e.g., carbon fiber reinforced plastic, a magnetic or conductive material, a glass fiber reinforced material, etc.), ceramic, sapphire, glass, and the like.

The elastic member 1000 may be flexible or foldable. That is, the elastic member 1000 may be folded or bent in one direction. That is, the elastic member 1000 may be a substrate for display applied to a flexible display device or a foldable display device.

In the elastic member 1000, a first direction 1D and a second direction 2D that is different from the first direction 1D may be defined. For example, the first direction 1D may be defined as the same direction as a folding axis direction of the elastic member 1000. In addition, the second direction may be a direction perpendicular to the first direction.

One direction of the first direction 1D and the second direction 2D may be defined as a width direction of the elastic member 1000, and the other direction may be defined as a longitudinal direction of the elastic member 1000.

The elastic member 1000 may be folded with any one of the width direction and the longitudinal direction of the elastic member 1000 as a folding axis.

Hereinafter, for convenience of description, the first direction is defined as the same direction as the folding axis. In addition, the first direction is defined as the width direction of the elastic member 1000, and the second direction is defined as the longitudinal direction of the elastic member 1000.

The elastic member 1000 may include at least two regions. In detail, the elastic member 1000 may include a first region 1A and a second region 2A.

The first region 1A may be defined as a region where the elastic member 1000 is folded. That is, the first region 1A may be defined as a region where the elastic member 1000 and the display device 10 including the elastic member 1000 are folded. That is, the first region 1A may be a folding region.

In addition, the second region 2A may be defined as a region where the elastic member 1000 is not folded. That is, the second region 2A may be defined as a region where the elastic member 1000 and the display device 10 including the elastic member 1000 are not folded. That is, the second region 2A may be an unfolding region.

The first region 1A and the second region 2A will be described in detail below.

The display panel 2000 may be disposed on the elastic member 1000.

The display panel 2000 may include a plurality of pixels including a switching thin film transistor, a driving thin film transistor, a power storage device, and an organic light-emitting diode (OLED). In case of the organic light-emitting diode, deposition is possible at a relatively low temperature and may be mainly applied to the flexible display device for reasons of low power and high luminance. Here, the pixel refers to a minimum unit for displaying an image, and the display panel displays an image through the plurality of pixels.

The display panel may include a substrate, a gate line disposed on the substrate, a data line isolated from the gate line, and a common power line. In general, one pixel may be defined by the gate line, the data line, and the common power line as a boundary.

The substrate may include a material having flexible properties such as a plastic film, and the display panel 2000 may be implemented by disposing an organic light-emitting diode and a pixel circuit on a flexible film.

The touch panel 3000 may be disposed above the display panel 2000. The touch panel 3000 may implement a touch function in the foldable display device or the flexible display device, and the touch panel may be omitted in a foldable display device or a flexible display device that simply displays an image without the touch function.

The touch panel 3000 may include a substrate and a touch electrode disposed on the substrate. The touch electrode may sense a position of an input device touched by the foldable display device or the flexible display device by a capacitive type or a resistive type.

The substrate of the touch panel 3000 may include a material having flexible properties such as a plastic film, and the touch panel 3000 may be implemented by disposing the touch electrode on the flexible film.

As described above, when the touch panel 3000 is integrally formed with the display panel 2000, the substrate of the touch panel 3000 may be a substrate of the display panel or a part of the display panel. Through this, the touch panel 3000 and the display panel 2000 can be integrally formed, and a thickness of the display device may be reduced.

Meanwhile, the elastic member 1000 and the display panel 2000 may have different sizes.

For example, an area of the elastic member 1000 may be 90% or more to 110% or less of an area of the display panel 2000. In detail, the area of the elastic member 1000 may be 95% or more to 105% or less of the area of the display panel 2000. In more detail, the area of the elastic member 1000 may be 97% or more to 100% or less of the area of the display panel 2000.

When the area of the elastic member 1000 is 90% or less of the area of the display panel 2000, support force of the elastic member 1000 supporting the display panel 2000 or the touch panel 3000 is decreased. Accordingly, a curl phenomenon or the like may occur in the unfolding region of the elastic member 1000. Accordingly, when a user visually recognizes a screen region, visibility may be deteriorated. In addition, when a touch is driven, a screen of a touch region may be incomplete due to a curled region, and thus a touch malfunction may occur.

In addition, when the area of the elastic member 1000 increases to be 110% or more of the area of the display panel 2000, the support force for supporting the display panel or the touch panel may be secured by the elastic member 1000, but a bezel region of a display device including the substrate, the display panel, and the touch panel may increase. Accordingly, it is impossible to provide a wide effective screen region to the user, which may cause inconvenience in using the display device.

Meanwhile, although not shown in the drawings, a cover window protecting the foldable display device or the flexible display device may be additionally disposed above the touch panel 3000 or above the display panel 2000 (when the touch panel is omitted).

Meanwhile, the elastic member 1000, the display panel 2000, and the touch panel 3000 may be adhered to each other through an adhesive layer or the like.

As described above, the display device includes the elastic member 1000.

Referring to FIG. 2, the elastic member 1000 may be bent in one direction.

In detail, the elastic member 1000 may include a first surface 1S and a second surface 2S opposite to the first surface 1S. In the elastic member 1000, the first surface 1S or the second surface 2S may be bent to face each other. That is, the elastic member 1000 may be bent so that the surfaces on which the panels are disposed face each other. Alternatively, the elastic member 1000 may be bent so that a surface opposite to the surface on which the panels are disposed faces.

However, the embodiment is not limited thereto, and the second surface and the first surface of the elastic member 1000 may be bent to alternately face each other. That is, the elastic member 1000 may include a plurality of first regions and a plurality of second regions.

In the following description, as shown in FIG. 2, it will be mainly described that the elastic member 1000 is bent in a direction in which the first surfaces 1S face each other.

As described above, the elastic member 1000 may have the first region 1A and the second region 2A defined therein. The first region 1A and the second region 2A may be regions defined when the elastic member 1000 is bent in the direction in which the first surfaces 1S face each other.

In detail, the elastic member 1000 is bent in one direction, and the elastic member 1000 may be divided into the first region 1A which is a folding region and the second region 2A which is an unfolding region.

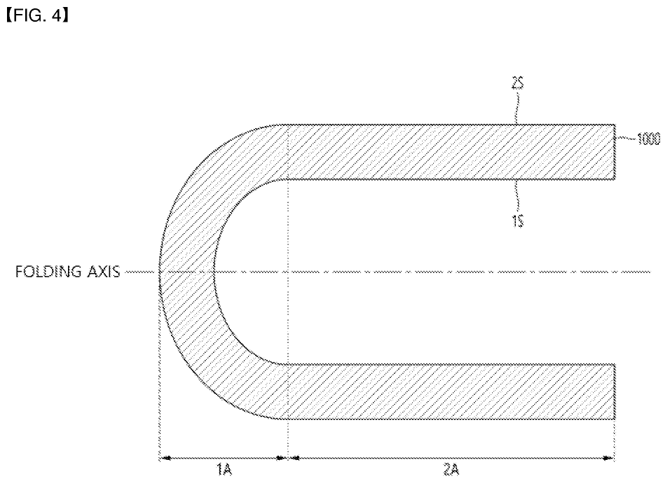

Referring to FIG. 3 and FIG. 4, the elastic member 1000 may include a first region 1A that is a region where the elastic member 1000 is bent. In addition, the elastic member 1000 may include a second region 2A that is disposed adjacent to the first region 1A. The second region 2A is not bent.

For example, the second region 2A may be formed on the left and right sides of the first region 1A, respectively, based on a bending direction of the elastic member 1000. That is, the second region 2A may be disposed at both ends of the first region 1A. That is, the first region 1A may be disposed between the second regions 2A.

However, the embodiment is not limited thereto, and the first region 1A may be further formed outside the second region 2A.

The first region 1A and the second region 2A may be formed on the same elastic member 1000. That is, the first region 1A and the second region 2A may be integrally formed on the same one elastic member 1000.

Sizes of the first region 1A and the second region 2A may be different. In detail, the size of the second region 2A may be greater than the size of the first region 1A.

In addition, an area of the first region 1A may be 1% or more to 30% or less of an entire area of the elastic member 1000. In detail, the area of the first region 1A may be 5% or more to 20% or less of the entire area of the elastic member 1000. The area of the first region 1A may be 10% or more to 15% or less of the entire area of the elastic member 1000.

When the area of the first region 1A is less than 1% of the entire area of the elastic member 1000, cracks may occur at the interface of the folding and unfolding regions of the elastic member 1000 when the folding and restoring of the substrate is repeated. Accordingly, folding reliability of the elastic member 10000 may be deteriorated.

In addition, when the area of the first region 1A of the elastic member 1000 exceeds 30% of the entire area of the elastic member 1000, curl may occur in the folding region of the display panel 2000 when the substrate is folded. Accordingly, when the user visually recognizes the screen region, the visibility may be deteriorated. In addition, when the touch is driven, the screen of the touch region may be incomplete due to the curled region, and thus the touch malfunction may occur.

In the drawings, it is illustrated that the first region 1A is positioned in a central portion of the elastic member 1000, but the embodiment is not limited thereto. That is, the first region 1A may be positioned in one end and an end region of the elastic member 1000. That is, the first region 1A may be positioned at one end and the end region of the elastic member 1000 such that the size of the first region 1A is asymmetric.

FIG. 4 is a side view of the substrate for display after the substrate is folded.

Referring to FIG. 4, the elastic member 1000 may be folded in one direction based on the folding axis. In detail, the first surfaces may be folded in a direction facing each other.

As the elastic member 1000 is folded in one direction, the first region 1A and the second region 2A may be formed on the elastic member 1000. That is, the elastic member 1000 may include the folding region and the unfolding region positioned at both ends of the folding region.

The folding region may be defined as a region where a curvature R is formed. In addition, the unfolding region may be defined as a region where the curvature R is not formed or the curvature is close to zero.

Referring to FIGS. 3 and 4, the elastic member 1000 may be folded in one direction to be formed in an order of the unfolding region, the folding region, and the unfolding region.

A plurality of pattern portions may be formed in at least one of the first region 1A and the second region 2A in order to reduce and distribute stress generated when the elastic member 1000 is folded. The pattern portions will be described in detail below.

Meanwhile, FIG. 4 illustrates that the first surfaces 1S of the elastic member 1000 are folded to face each other, but the embodiment is not limited thereto, and the second surfaces 2S may be folded to face each other.

In addition, FIG. 4 illustrates that the curvature is decreased (a radius of the curvature is increased) while the elastic member 1000 extends from a center of the folding axis, but the embodiment is not limited thereto. For example, the curvature may decrease or increase while the elastic member 1000 extends from the center of the folding axis. That is, the curvature may decrease and then increase while the elastic member 1000 extends from the center of the folding axis. Alternatively, the elastic member 1000 may be formed in a shape in which the curvature decreases and then increases, and then decreases again while extending from the center of the folding axis. That is, a folding shape of the elastic member 1000 may be formed in various folding shapes as well as a U-shaped shape.

As the elastic member 1000 according to the embodiment is repeatedly folded and restored, wrinkles may occur in the folding region. That is, as the elastic member 1000 is repeatedly folded and restored, the flatness of the folding region may be increased. Accordingly, wrinkles in the folding region of the elastic member 1000 may be visually recognized from the outside. In addition, cracks may occur in the folding region, and thus the reliability of the elastic member may be deteriorated.

Hereinafter, the elastic member capable of preventing an increase in flatness in the folding region when the elastic member is folded and restored by controlling a size of the folding region of the elastic member and a pattern formed in the folding region will be described.

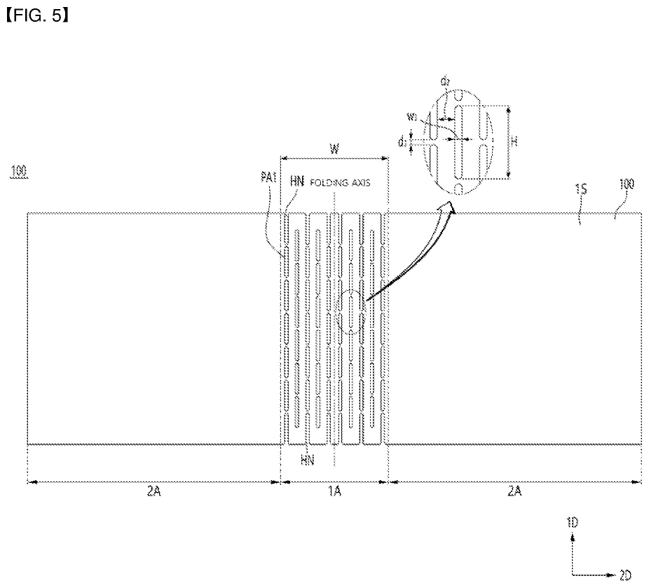

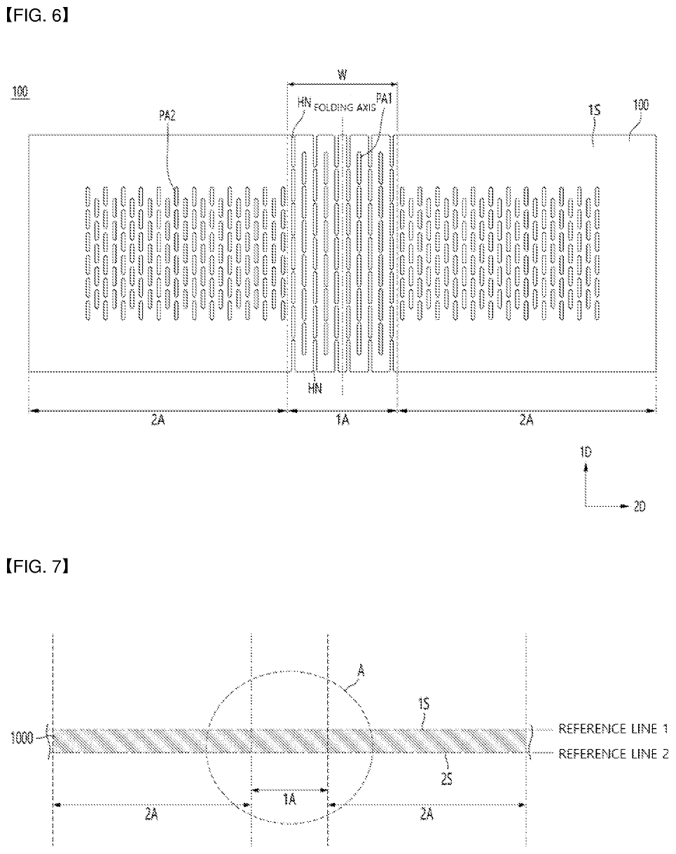

FIGS. 5 and 6 are top views of the elastic member 1000. In detail, they are views illustrating a first layer 100 of the elastic member.

Referring to FIGS. 5 and 6, the elastic member 1000 includes the first region 1A as a folding region and the second region 2A as an unfolding region.

The first region 1A and the second region 2A are formed to have different widths. In detail, a width of the first region 1A is smaller than a width of the second region 2A.

The first region 1A has a width within a set size range. The width of the first region 1A is defined as a width extending in the second direction 2D. A width W of the first region 1A has a width within a set size range. In detail, the width W of the first region 1A is 15 mm or more. In more detail, the width W of the first region 1A is 18 mm or more. In more detail, the width W of the first region 1A is 35 mm or more. For example, the width W of the first region 1A is 15 mm to 40 mm.

When the width W of the first region 1A is less than 15 mm, the flatness of the elastic member 1000 increases. Accordingly, the folding reliability of the elastic member 1000 may be deteriorated. In addition, when the width W of the first region 1A exceeds 40 mm, the size of the elastic member may be increased by increasing the width of the first region 1A.

Referring to FIG. 5, the elastic member 1000 may include a plurality of pattern portions PA. In detail, the elastic member 1000 may include a first pattern portion PA1 disposed in the first region 1A. The first pattern portion PA1 may reduce compressive stress and tensile stress that are generated when the elastic member 1000 is folded and restored.

The first pattern portion PA1 may be formed in a hole or groove shape.

In detail, the first pattern portion PA is formed in a hole shape penetrating the first surface 1S and the second surface 2S opposite to the first surface 1S of the elastic member 1000. Alternatively, the first pattern portion PA is formed in a groove shape formed on the first surface 1S or the second surface 2S.

The elastic member 1000 may be easily folded by the first pattern portion PA1 disposed in the first region 1A. In detail, in the elastic member 1000, a thickness of the elastic member 1000 is reduced in the folding region by the first pattern portion PA1. Accordingly, since the compressive stress is reduced, the elastic member 1000 may be easily folded.

In addition, referring to FIG. 6, the elastic member 1000 may further include a second pattern portion PA2. In detail, the elastic member 1000 may further include the second pattern portion PA2 disposed in the second region 2A.

The second pattern portion PA2 may be formed in a hole or groove shape.

In detail, the second pattern portion PA may be formed in a hole shape penetrating the first surface 1S and the second surface 2S of the elastic member 1000. Alternatively, the second pattern portion PA may be formed in a groove shape formed on the first surface 1S or the second surface 2S.

The second pattern portion PA2 disposed in the second region 2A may make the physical characteristics of the first region 1A and the second region 2A similar.

In detail, a difference in thermal deformation between the first region 1A and the second region 2A may be reduced. That is, since pattern portions are formed in both the first region 1A and the second region 2A, when heat is applied to the elastic member 1000, the difference in thermal deformation between the first region 1A and the second region 2A may be reduced. Accordingly, it is possible to prevent the elastic member 1000 from being bent or twisted due to the difference in deformation between the first region 1A and the second region 2A.

In addition, since unevenness of the stress between the first region 1A and the second region 2A is reduced by the second pattern portion PA2 formed in the second region 2A, it is possible to prevent bending of the elastic member.

The second pattern portion PA2 may be formed in a shape the same as or similar to that of the first pattern portion PA1. In detail, the second pattern portion PA2 may be formed in a shape having a longitudinal direction and a transverse direction, and a longitudinal direction of the second pattern portion PA1 and a longitudinal direction of the first pattern portion PA1 may extend the same or similar directions to each other, and a transverse direction of the second pattern portion PA2 and a transverse direction of the first pattern portion PA1 may extend in the same or similar directions to each other.

Meanwhile, the elastic member 1000 may include a hinge portion HN. In detail, a plurality of hinge portions HN may be disposed in the first region 1A. The hinge portion HN is a region where an end region of the elastic member 1000 is opened for folding of the elastic member 1000. In addition, the hinge portion HN may be formed only in the first region 1A. Accordingly, the hinge portion HN becomes a point at which folding of the elastic member 1000 is started. The first region 1A and the second region 2A may be divided according to whether the hinge part is formed or not.

A size and distance of the first pattern portion PA1 have a set size,

In detail, the first pattern portion PA1 includes a first distance d1 in the first direction 1D, a second distance d2 in the second direction 2D, a height H in the first direction, and a width w1 in the second direction.

The first distance d1 may have a size within a set range. In detail, the first distance d1 may be 1 mm or less. In more detail, the first distance d1 may be 0.1 mm to 1 mm. In more detail, the first distance d1 may be 0.5 mm to 1 mm.

When the first distance d1 exceeds 1 mm, the distance between the first pattern portions PA1 increases, so that an area in which the first pattern portion PA1 is not formed in the first direction increases. Accordingly, the magnitude of stress generated in the first region 1A may increase.

The second distance d2 may have a size within a set range. In detail, the second distance d2 may be 0.15 mm or less. In more detail, the second distance d2 may be 0.05 mm to 0.15 mm.

When the second distance d2 exceeds 0.15 mm, the distance between the first pattern portions PA1 increases in the second direction, so that an area in which the first pattern portion PA1 is not formed increases. Accordingly, the magnitude of stress generated in the first region 1A may increase.

The height H may have a size within a set range. In detail, the height H may be 5 mm or less. In more detail, the height H may be 1 mm to 5 mm. In more detail, the height H may be 2 mm to 4 mm.

When the height H exceeds 5 mm, an area in which the first pattern portions PA1 are formed increases in the second direction, and thus an area in which the first pattern portions PA1 are formed increases. Accordingly, the elasticity of the first region 1A may be deteriorated.

The width w1 may have a size within a set range. In detail, the width w1 may be 0.22 mm or less. In more detail, the width w1 may be 0.1 mm to 0.22 mm.

When the width w1 exceeds 0.22 mm, the area in which the first pattern portions PA1 are formed in the second direction increases, and thus the area in which the first pattern portion PA1 is formed increases. Accordingly, the elasticity of the first region 1A may be deteriorated.

Hereinafter. The flatness of the elastic member according to the embodiment will be described with reference to FIGS. 7 to 11.

Referring to FIGS. 7 to 9 are views for describing the flatness of the elastic member according to the embodiment.

Referring to FIG. 7, in the elastic member 1000, reference lines extending from the first surface 1S and the second surface 2S may be defined. For example, in the elastic member 1000, a first reference line extending from the first surface 1S and a second reference line extending from the second surface 2S may be defined.

The first reference line is defined as a line extending in a parallel direction from the second region of the first surface 1S. In addition, the second reference line is defined as a line extending in a parallel direction from the second region of the second surface 2S.

As described above, in the elastic member 1000, the flatness may be increased in a region adjacent to the first region 1A that is a folding region while repeating folding and restoring.

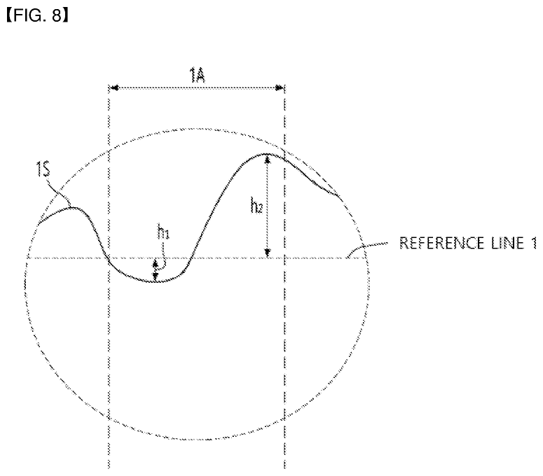

The flatness of the elastic member may be defined as shown in FIGS. 8 to 11.

Referring to FIGS. 8 and 9, the first surface 1S may have a height difference from the first reference line (or a starting point of the folding region) in the first region 1A and the second region 2A. The first region 1A may have a relatively large height difference compared to the second region 2A.

In detail, the first surface 1S of the first region 1A has a first height having the greatest height below the first reference line (or the starting point of the folding region). In addition, the first surface 1S of the first region 1A has a second height having the greatest height above the first reference line (or the starting point of the folding region).

For example, referring to FIG. 8, when the first reference line is defined as zero, the first surface 1S has a first height h1 having a negative maximum height with respect to the first reference line. In addition, the second surface 2S has a second height h2 having a positive maximum height with respect to the first reference line.

Alternatively, referring to FIG. 9, when starting points P1 and P2 of the first region 1A are defined as zero, the first surface 1S has first heights h1′ and h1″ having a negative maximum height with respect to the starting points P1 and P2 of the first region 1A. In addition, the first surface 1S has second heights h2′ and h2″ having a positive maximum height with respect to the starting points P1 and P2 of the first region 1A.

In this case, the flatness of the elastic member 1000 may be defined as the sum h1+h2, h1′+h2′, and h1″+h2″ of first heights h1, h1′, and h1″ and second heights h2, h2′, and h2″. That is, the flatness of the elastic member 1000 may be defined as the sum of the negative maximum height and the positive maximum height based on the first reference line (or the starting point of the first region 1A).

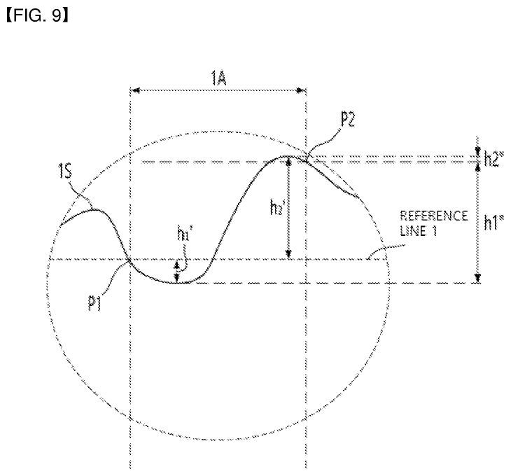

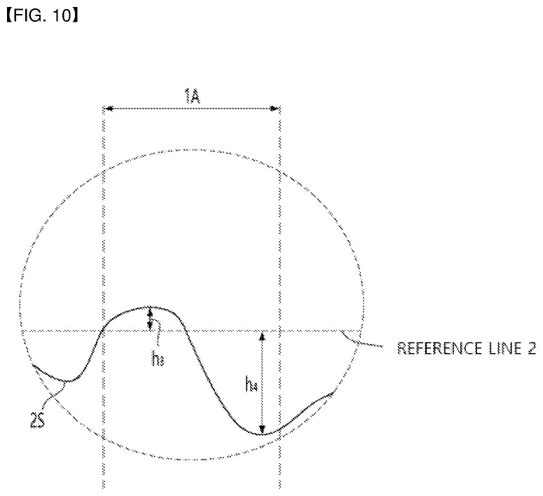

In addition, referring to FIGS. 10 and 11, the second surface 2S may have a height difference from the second reference line (or the starting point of the folding region) in the first region 1A and the second region 2A. The first region 1A may have the relatively large height difference compared to the second region 2A.

In detail, the second surface 2S of the first region 1A has a third height h3 having the greatest height above the second reference line (or the starting point of the folding region). In addition, the second surface 2S may have a fourth height h4 having the greatest height below the second reference line (or the starting point of the folding region).

For example, referring to FIG. 10, when the second reference line is defined as zero, the second surface 2S has the third height h3 having a positive maximum height with respect to the second reference line. In addition, the second surface 2S has the fourth height h4 having a negative maximum height with respect to the second reference line.

Alternatively, referring to FIG. 11, when the starting points P1 and P2 of the first region 1A that is a folding region are defined as zero, the second surface 2S has third heights h3′ and h3″ having a positive maximum height with respect to the starting points P1 and P2 of the first region 1A. In addition, the second surface 2S may have fourth heights h4′ and h4″ having a maximum negative height with respect to the starting points P1 and P2 of the first region 1A.

In this case, the flatness of the elastic member 1000 may be defined as the sum h3+h4, h3′+h4′, and h3″+h4″ of the third height h3, h3′, and h3″ and the fourth height h4, h4′, and h4″. That is, the flatness of the elastic member 1000 may be defined as the sum of the negative maximum height and the positive maximum height based on the second reference line (or the starting point of the first region 1A).

In the elastic member 1000 according to the embodiment, the width of the first region 1A of the elastic member 1000 described above is set to the set size. Accordingly, the magnitude of the flatness of the elastic member may be reduced. Accordingly, it is possible to prevent a shape of the first region 1A from being changed even when folding and restoring are repeated. In addition, it is possible to prevent cracks from occurring in the first region 1A by increasing the flatness of the elastic member.

That is, in the elastic member 1000 according to the embodiment, the width of the first region 1A may be 15 mm or more. Accordingly, in the first region, the compressive stress and tensile stress generated due to folding and restoring are distributed over a large area. Accordingly, it is possible to prevent stress from being concentrated in a specific region. In addition, it is possible to reduce stress per unit area in the folding region.

Accordingly. It is possible to reduce the magnitude of flatness that may be increased by increasing the magnitude of the stress. Therefore, it is possible to increase the lifespan of the elastic member 1000 and to prevent the folding reliability from being deteriorated due to deformation of the folding region.

Hereinafter, the present invention will be described in more detail through the flatness of elastic members according to Examples and Comparative Examples. The embodiments are merely presented as examples in order to explain the present invention in more detail. Therefore, the present invention is not limited to these examples.

### EXAMPLE

A sample of the elastic member was manufactured by adhering a stainless steel (SUS) substrate and a polyimide (PI) substrate through an adhesive layer.

At this time, a size of the sample was 60 mm*130 mm, and a width of the folding region was 15 mm.

Next, after folding the sample of the elastic member 200,000 times with a radius of curvature of 1.5 R (mm) at a room temperature (25° C.), a process of restoring was performed again.

Then, in a central region of the elastic member sample, a length of 30 mm including both the folding region and the unfolding region was measured with an Alpha-step equipment. Accordingly, the maximum and minimum values of a surface height were measured.

### COMPARATIVE EXAMPLE

Except that the width of the folding region was 10 mm, the length of 30 mm including both the folding region and the unfolding region in the central region of the elastic member sample was measured with the Alpha-step equipment in the same manner as in the Example. Accordingly, the maximum and minimum values of the surface height were measured.

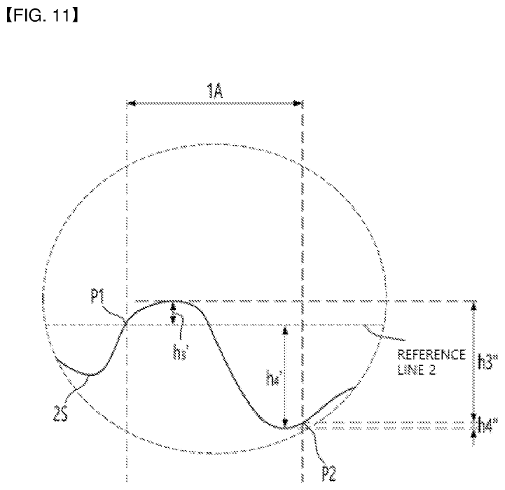

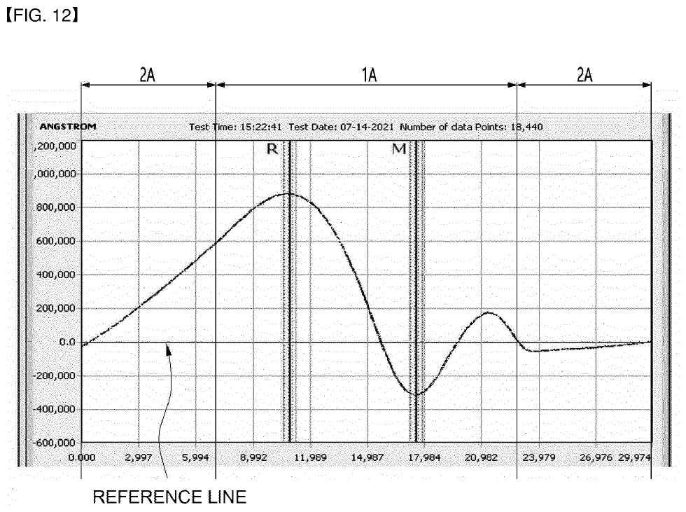

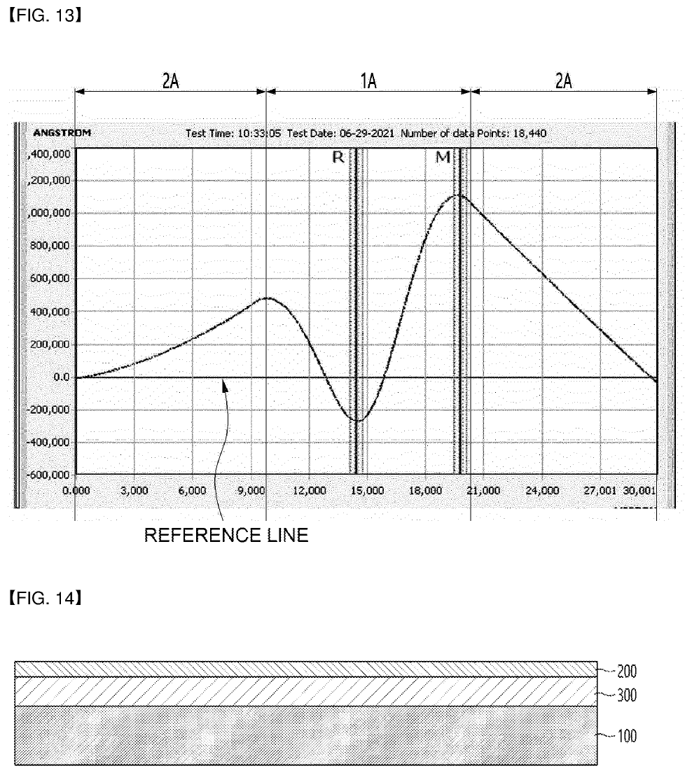

FIG. 12 is a graph illustrating a difference in surface heights of the folding region and the unfolding region according to Example, and FIG. 13 is a graph illustrating a difference in surface heights of the folding region and the unfolding region according to Comparative Example.

Referring to FIG. 12, in the elastic member according to Example, in the first region 1A that is a folding region, the magnitude of the flatness, which is a difference between the maximum value and the minimum value in height, is about 118 μm. On the other hand, referring to FIG. 13, in the elastic member according to Comparative Example, in the first region 1A that is a folding region, the magnitude of the flatness, which is the difference between the maximum value and the minimum value in height, is about 136 μm.

That is, it can be seen that the magnitude of the flatness of the folding may be reduced by making the width of the folding region of the elastic member according to Example greater than the width of the folding region of the elastic member according to Comparative Example and by efficiently distributing the stress in the folding region.

That is, the magnitude of the flatness of the folding may be reduced by making the magnitude of stress per unit area generated in the folding region of the elastic member according to Example smaller than the magnitude of stress per unit area of the elastic member according to Comparative Example.

Hereinafter, a layer structure of the elastic member described above will be described with reference to FIGS. 14 to 16.

FIGS. 14 to 16 are cross-sectional views for describing various layer structures of the elastic member 1000.

Referring to FIG. 14, the elastic member 1000 may include a first layer 100, a second layer 200, and a third layer 300. In detail, the elastic member 1000 may include the first layer 100, the second layer 200 on the first layer 100, and the third layer 300 between the first layer 100 and the second layer 200.

The first layer 100 may include a metal. In detail, the first layer 100 may include a metal or a metal alloy. For example, the first layer 100 may include SUS or copper (Cu). Alternatively, the first layer 100 may be formed of an alloy including at least one of nickel (Ni), chromium (Cr), iron (Fe), titanium (Ti), manganese (Mn), molybdenum (Mo), silver (Ag), zinc (Zn), nitrogen (N), and aluminum (Al) together with copper (Cu).

The second layer 200 may be disposed on the first layer 100.

The second layer 200 is disposed on the first layer 100 to planarize a surface of the first layer 100. As described above, a plurality of pattern portions in a hole or groove shape are formed in the first layer 100. Accordingly, the surface of the first layer 100 is not flat due to the pattern portions. Accordingly, when a panel or the like is directly adhered to the first layer 100, the adhesion to the panel may be reduced due to surface characteristics of the first layer 100.

Accordingly, the elastic member 1000 may dispose the second layer 200 on the first layer 100 to flatten an adhesive surface on which the elastic member 1000 is adhered to the panel. That is, the second layer 100 may be defined as a planarization layer of the elastic member 1000.

The second layer 200 may include a metal or a non-metal. In detail, the second layer 200 may include a metal or plastic. The second layer 200 may include different materials according to characteristics to be implemented in folding characteristics and strength among characteristics of the elastic member 1000.

For example, the second layer 200 may include plastic. For example, the second layer 200 may include polyimide (PI), but the embodiment is not limited thereto.

The third layer 300 may be disposed between the first layer 100 and the second layer 200. The third layer 300 may be disposed between the first layer 100 and the second layer 200 to adhere the first layer 100 and the second layer 200. That is, the third layer 300 may serve as an adhesive layer in the elastic member 1000.

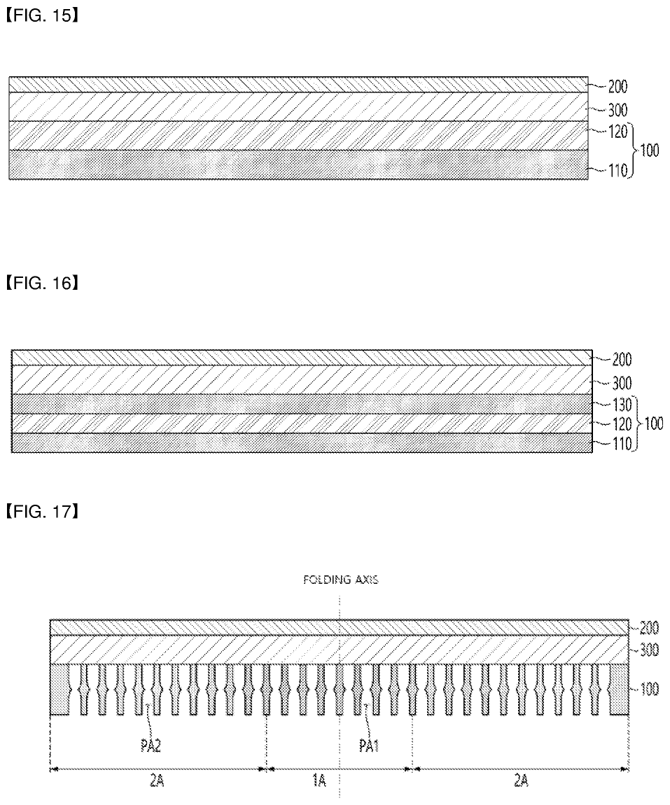

Referring to FIGS. 15 and 16, the first layer 100 may be formed in multiple layers.

Referring to FIG. 15, the first layer 100 may include a 1-1 layer 110 and a 1-2 layer 120 on the 1-1 layer 110.

The 1-1 layer 110 and the 1-2 layer 120 may include a metal material. In detail, the 1-1 layer 110 and the 1-2 layer 120 may include different metal materials.

For example, the 1-1 layer 110 and the 1-2 layer 120 may include materials having different thermal conductivity. In detail, the 1-1 layer 110 may include a material having thermal conductivity higher than that of the 1-2 layer 120.

In addition, the 1-1 layer 110 and the 1-2 layer 120 may include materials having different yield strengths. In detail, the 1-2 layer 120 may include a material having a yield strength higher than that of the 1-1 layer 110.

For example, the 1-1 layer 110 may include copper or a copper alloy, and the 1-2 layer 120 may include SUS, but the embodiment is not limited thereto, and the 1-1 layer 110 and the 1-2 layer 120 may include various materials satisfying the thermal conductivity and the yield strength.

In addition, the 1-1 layer 110 and the 1-2 layer 120 may be disposed in direct contact with each other. In detail, the 1-1 layer 110 and the 1-2 layer 120 may be manufactured in a clad method.

Clad bonding is a method of bonding the 1-1 layer 110 and the 1-2 layer 120 by a method such as welding, rolling, casting, or extrusion without bonding using an adhesive, and it is possible to show better bonding force over time by destroying a mutual organization of each layer and stabilizing the bonding of each layer through interstitial penetration.

For example, the bonding may be formed by inducing atomic diffusion between dissimilar materials at a layer interface of different layers through rolling. Since the clad bonding may process curved surfaces unlike bonding using an adhesive and uses atomic diffusion bonding rather than bonding using the adhesive, it has an advantage of being able to maintain a bonded state for a long time.

The 1-1 layer 110 and the 1-2 layer 120 may be disposed to have the same or different thicknesses. For example, when it is desired to improve heat dissipation characteristics of the elastic member 1000, a thickness of the 1-1 layer 110 may be disposed to be greater than a thickness of the 1-2 layer 120. Alternatively, in order to improve folding properties of the elastic member 1000, the thickness of the 1-2 layer 120 may be greater than the thickness of the 1-1 layer 110.

That is, the thickness of the 1-1 layer 110 and the thickness of the 1-2 layer 120 may vary according to characteristics to be implemented in the elastic member 1000.

Referring to FIG. 16, the first layer 100 may include a 1-1 layer 110, a 1-2 layer 120 on the 1-1 layer 110, and a 1-3 layer 130 on the 1-2 layer 120.

The 1-1 layer 110, the 1-2 layer 120, and the 1-3 layer 130 may include a metal material. In detail, the 1-1 layer 110, the 1-2 layer 120, and the 1-3 layer 130 may include the same or different metal materials.

For example, the 1-1 layer 110 and the 1-3 layer 130 may include the same material from each other, and the 1-2 layer 120 may include a material different from those of the 1-1 layer 110 and the 1-3 layer 130.

The 1-1 layer 110, the 1-3 layer 130, and the 1-2 layer 120 may include materials having different thermal conductivity. In detail, the 1-1 layer 110 and the 1-3 layer 130 may include a material having thermal conductivity higher than that of the first 1-2 layer 120.

In addition, the 1-1 layer 110, the 1-3 layer 130, and the 1-2 layer 120 may include materials having different yield strengths. In detail, the first 1-2 layer 120 may include a material having a yield strength higher than those of the 1-1 layer 110 and the 1-3 layer 130.

For example, the 1-1 layer 110 and the 1-3 layer 130 may include copper or a copper alloy, and the first 1-2 layer 120 may include SUS, but the embodiment is not limited thereto, and the 1-1 layer 110, the 1-2 layer 120, and the 1-3 layer 130 may include various materials satisfying the thermal conductivity and the yield strength.

In addition, the 1-1 layer 110, the 1-2 layer 120, and the 1-3 layer 130 may be disposed in direct contact with each other. In detail, the 1-1 layer 110, the 1-2 layer 120, and the 1-3 layer 130 may be manufactured by the clad method described above.

The 1-1 layer 110, the 1-2 layer 120, and the 1-3 layer 130 may be disposed to have the same or different thicknesses from each other. For example, when it is desired to improve the heat dissipation characteristics of the elastic member 1000, the thickness of the 1-1 layer 110 and the thickness of the 1-3 layer 130 may be disposed to be greater than the thickness of the 1-2 layer 120. Alternatively, when it is desired to improve the folding properties of the elastic member 1000, the thickness of the 1-2 layer 120 may be disposed to be greater than those of the 1-1 layer 110 and the 1-3 layer 130.

That is, the thickness of the 1-1 layer 110, the thickness of the first 1-2 layer 120, and the thickness of the 1-3 layer 130 may vary depending on the properties to be implemented in the elastic member 1000.

Consequently, the first layer of the elastic member may include at least one of the 1-1 layer, the 1-2 layer, and the 1-3 layer.

FIGS. 17 and 18 are views for describing arrangement relationship of the third layer 300.

Referring to FIG. 17, the third layer 300 may be disposed on an upper surface of the first layer 100. In detail, after disposing the third layer 300 on the first layer 100 and disposing the second layer 200 on the third layer 300, the first layer 100 and the second layer 200 may be adhered through the third layer 300 by applying pressure on the upper surface.

In this case, the third layer 300 is not disposed inside the first pattern portion PA1 and the second pattern portion PA2 formed on the first layer 100, but the third layer 300 may be disposed only on the upper surface of the first layer 100.

Since the third layer is not disposed inside pattern portions of the first layer, when the elastic member is applied to the display device, refraction and total reflection of light according to the third layer may be minimized, so that light transmittance may be improved.

Alternatively, referring to FIG. 18, the third layer 300 may be disposed on the upper surface of the first layer 100. In detail, the third layer 300 may be disposed inside the first pattern portion PA1 and the second pattern portion PA2 of the first layer 100. In detail, the third layer 300 may be disposed while filling the inside of the first pattern portion PA1 and the second pattern portion PA2 in whole as shown in FIG. 12 or may be disposed while filling the inside of the first pattern portion PA1 and the second pattern portion PA2 in part.

In detail, after disposing the third layer 300 on the first layer 100 and disposing the second layer 200 on the third layer 300, the third layer 300 may adhere the first layer100 and the second layer 200 while applying pressure onto the second layer 200 and filling both the inside of the first pattern portion PA1 and the second pattern portion PA2 in whole or in part.

Since the third layer is disposed inside the pattern portions of the first layer, when bonding the first layer and the second layer through the third layer, it is possible to improve the adhesive properties by making an area to which the pressure is applied uniform in a first region and a second region of the first layer.

In addition, it is possible to prevent impurities from penetrating through the pattern portions of the first layer.

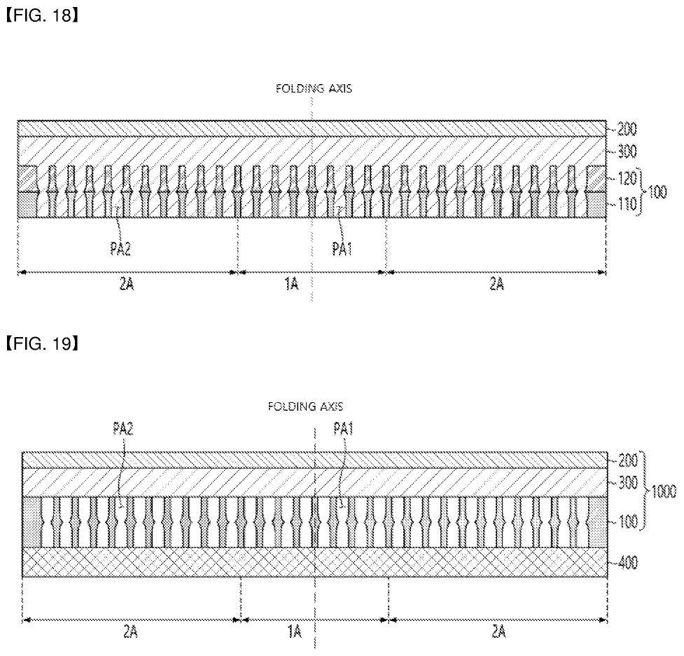

Hereinafter, a folding support including the elastic member according to the embodiment described above will be described with reference to FIGS. 19 and 20.

Referring to FIGS. 19 and 20, the folding support may include the elastic member and a protective layer 400. FIG. 19 is a view showing a folding support in which the third layer is not disposed inside the pattern portion of the first layer, and FIG. 20 is a view showing a folding support in which the third layer formed of a plurality of layers is disposed inside the pattern portion of the first layer.

The folding support may include the above-described elastic member 1000 and the protective layer 400 disposed under the elastic member 10. In detail, the protective layer 400 may be disposed under the first layer 100 or the 1-1 layer 110 of the elastic member 1000.

Although not shown in the drawings, an adhesive layer is disposed between the protective layer 400 and the first layer 100 or between the protective layer 400 and the 1-1 layer 110, and the elastic member 1000 and the protective layer 400 may be adhered through the adhesive layer.

The protective layer 400 may have a color. For example, the protective layer 400 may be formed in a black-based color.

The protective layer 400 may include metal particles. For example, the protective layer 400 may include copper particles. Accordingly, heat generated in the display device may be dissipated through the protective layer 400 by improving a thermal conductivity of the protective layer 400.

The protective layer 400 may be disposed on one region of the elastic member 1000. In detail, the protective layer 400 may be disposed in a region corresponding to the first region 1A of the elastic member 1000. Alternatively, the protective layer 400 may be disposed in a region corresponding to the first region 1A and the second region 2A of the elastic member 1000.

For example, the protective layer 400 may be disposed in a region corresponding to the first region 1A and the second region 2A of the elastic member 1000 and may be disposed in an area smaller than the sum of areas of the first region 1A and the second region 2A. In detail, the protective layer 400 may be disposed in an area of 80% to 90% of the sum of the areas of the first region 1A and the second region 2A of the elastic member.

In addition, a thickness of the protective layer 400 may be smaller than the overall thickness of the elastic member 1000. That is, the thickness of the protective layer 400 may be smaller than the sum of thicknesses of the first layer, the second layer, and the third layer of the elastic member 400.

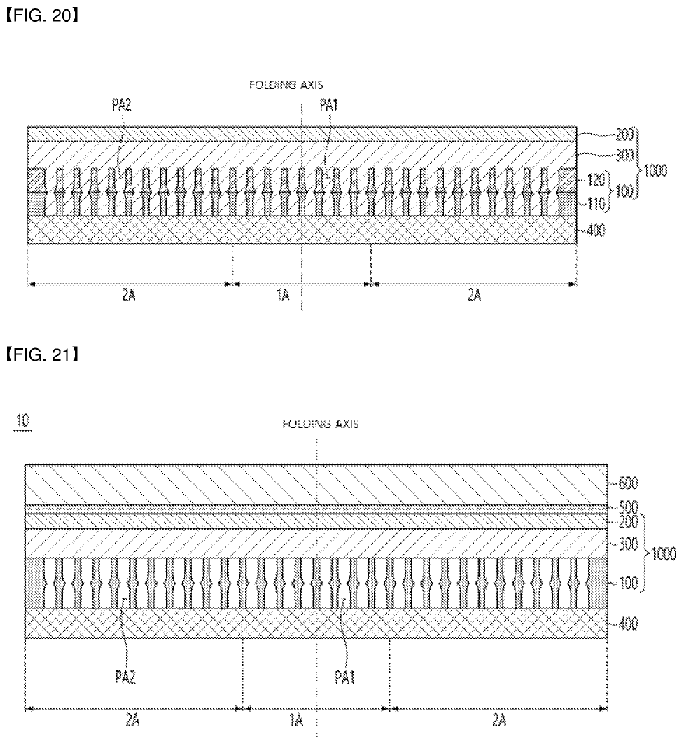

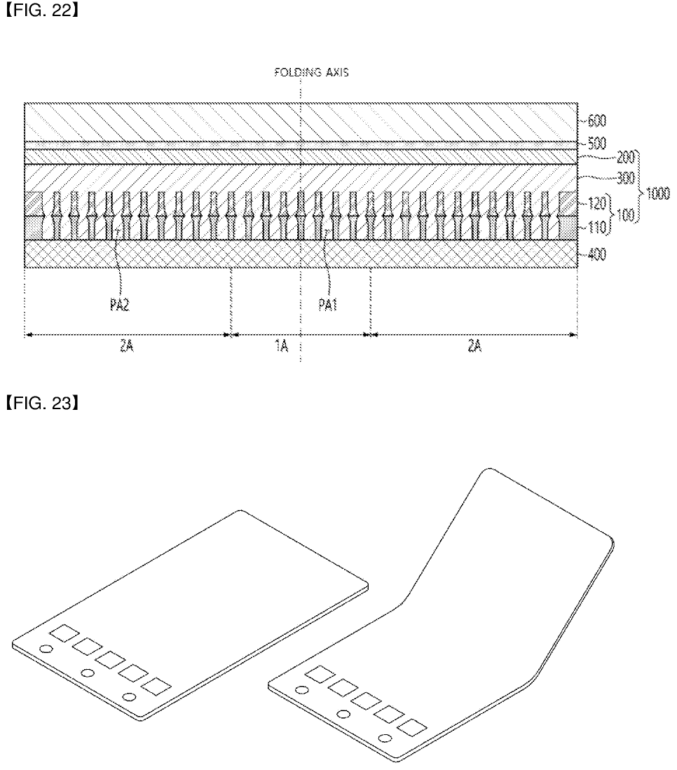

Hereinafter, a display device including the folding support according to the embodiment described above will be described with reference to FIGS. 21 and 22.

Referring to FIGS. 21 and 22, the display device 10 may include the folding support and the panel. FIG. 21 is a view showing a display device in which the third layer of the elastic member is not disposed inside the pattern portion of the first layer, and FIG. 22 is a view showing a display device in which the third layer formed of a plurality of layers is disposed inside the pattern portion of the first layer.

The display device 10 may include the folding support and a panel layer 600 that is disposed on the folding support and includes a display panel and/or a touch panel.

The folding support may include the elastic member 1000 including the first layer 100, the second layer 200, and the third layer 300 described above and the protective layer 400 disposed under the elastic member 1000. In detail, the protective layer 400 may be disposed under the first layer 100 or the 1-1 layer 110 of the elastic member 1000.

An adhesive layer 500 may be disposed between the elastic member 1000 and the panel layer 600, and the elastic member 1000 may be adhered to the panel layer 600 through the adhesive layer 500.

As described above, since the elastic member 1000 may planarize an adhesive surface of the elastic member by the second layer 200, the elastic member and the panel layer may be stably adhered to each other without being affected by a step difference.

The adhesive layer 500 between the elastic member 1000 and the panel layer 600 may have different properties from the third layer 300 of the elastic member 1000.

In detail, the adhesive layer 500 may have a thickness smaller than that of the third layer 300. For example, the thickness of the adhesive layer 500 may be 5 μm to 15 μm.

In addition, the adhesive layer 500 may have smaller adhesive properties than the third layer 300. In detail, an adhesive force of the adhesive layer 500 may be 400 or less.

In addition, the adhesive layer 500 and the third layer 300 may have different elastic moduli. That is, the adhesive layer 500 does not have an elastic modulus having a storage modulus, creep & recovery and a tangent delta value like the third layer, whereby the adhesive layer 500 may not have elastic properties other than adhesive properties.

FIG. 23 is a view for describing an example in which the elastic member according to the embodiments is applied.

Referring to FIG. 23, the elastic member according to the embodiments may be applied to a flexible or foldable display device for displaying a display.

For example, the elastic member according to the embodiments may be applied to a flexible display device such as a mobile phone or a tablet.

Such an elastic member may be applied to a flexible display device such as a mobile phone or a tablet that is flexible, bent, or folded.

The elastic member is applied to the flexible display device such as the mobile phone or the tablet that is flexible, bent or folded and improves the folding reliability in a display device that is repeatedly folded or folded, thereby improving the reliability of the flexible display device.

The characteristics, structures and effects described in the embodiments above are included in at least one embodiment but are not limited to one embodiment. Furthermore, the characteristic, structure, and effect illustrated in each embodiment may be combined or modified for other embodiments by a person skilled in the art. Thus, it should be construed that contents related to such a combination and such a modification are included in the scope of the present disclosure.

In addition, embodiments are mostly described above, but the embodiments are merely examples and do not limit the present disclosure, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present disclosure defined in the following claims.

1. An elastic member foldable based on a folding axis, the elastic member comprising:
a first region including the folding axis and a second region provided around the first region,
wherein the elastic member is defined in a first direction corresponding to the folding axis and a second direction perpendicular to the first direction,
wherein the second region is located farther from the folding axis in the second direction than the first region,
wherein the first region is a region including a plurality of hinge portions, and the second region is a region excluding the first region,
wherein the hinge portion is a region where at least one of a first side end and a second side end of the elastic member located in the first direction is open,
wherein a width of the first region in the second direction is smaller than a width of the second region in the second direction, and
wherein the width of the first region in the second direction is 15 mm or more.

2. The elastic member of claim 1, wherein the width of the first region in the second direction is 15 mm to 40 mm.

3. The elastic member of claim 1, wherein the first region includes a plurality of first pattern portions entirely or partially penetrating the elastic member,
wherein The first pattern portion includes a plurality of first patterns spaced apart from each other in the first direction,
wherein a width of the plurality of first patterns in the second direction is 0.1 mm to 0.22 mm, and
wherein a length of the plurality of first patterns in the first direction is 1 mm to 5 mm.

4. The elastic member of claim 3, wherein the plurality of first patterns are provided to be spaced apart from each other in the second direction, and
wherein a distance of the plurality of first patterns in the second direction is 0.05 mm to 0.15 mm.

5. The elastic member of claim 1, wherein a flatness defined as the sum (first height+second height) of a first height of a surface of the elastic member having a positive height at a starting point of the first region and a second height of the surface of the elastic member having a negative height at the starting point of the first region is defined in the first region, and
a magnitude of the flatness of the first region is 100 μm to 130 μm.

6. The elastic member of claim 1, wherein a first reference line extending in a parallel direction in the second region of the first surface of the elastic member is defined,
when the first reference line is defined as zero, the flatness defined as the sum (first height+second height) of the first height having a negative maximum height with respect to the first reference line and the second height having a positive maximum height with respect to the first reference line is defined, and
the magnitude of the flatness of the first region is 100 μm to 130 μm.

7. The elastic member of claim 1, wherein a second reference line extending in a parallel direction in the second region of the second surface of the elastic member is defined,
when the second reference line is defined as zero, the flatness defined as the sum (first height+second height) of the first height having a positive maximum height with respect to the second reference line and the second height having a negative maximum height with respect to the second reference line is defined, and
the flatness size of the first region is 100 μm to 130 μm.

8. The elastic member of claim 1, further comprising:
a first layer; and a second layer on the first layer,
wherein the first layer and the second layer include different materials.

9. The elastic member of claim 3, wherein the plurality of first patterns are not connected to the first side end and the second side end of the elastic member located in the first direction, and
wherein lengths of the plurality of first patterns in the first direction are same, and
wherein widths of the plurality of first patterns in the second direction are same.

10. The elastic member of claim 4, wherein the first pattern portion includes at least first to third groups of first pattern portions spaced apart from each other in the second direction,
wherein a distance between the first pattern portion of the first group and the first pattern portion of the second group in the second direction is same as a distance between the first pattern portion of the second group and the first pattern portion of the third group in the second direction.

11. The elastic member of claim 4, further comprising:
a second pattern portion disposed in the second region,
wherein the second pattern portion includes a plurality of second patterns spaced apart from each other in the first direction,
wherein a length of the plurality of second patterns in the first direction is different from a length of the plurality of first patterns in the first direction.

12. The elastic member of claim 11, wherein a length of the plurality of second patterns in the first direction is smaller than a length of the plurality of first patterns in the first direction.

13. The elastic member of claim 11, wherein the first pattern portion includes a first outer pattern that is not connected to the first side end and is closest to the first side end,
wherein the second pattern portion includes a second outer pattern that is not connected to the first side end and is closest to the first side end, and
wherein a distance from the first side end to the first outer pattern in the first direction is smaller than a distance from the first side end to the second outer pattern in the first direction.

14. The elastic member of claim 11, wherein the width of the plurality of first patterns in the second direction is equal to the width of the plurality of second patterns in the second direction.

15. The elastic member of claim 11, wherein the plurality of second patterns are arranged to be spaced apart from each other in the second direction, and
wherein distances in the second direction between the plurality of second patterns spaced apart in the second direction are equal to each other.

16. The elastic member of claim 15, wherein the distance of the plurality of second patterns in the second direction is same as the distance of the plurality of first patterns in the second direction.

17. The elastic member of claim 15, wherein the distance of the plurality of first patterns in the first direction is different from the distance of the plurality of second patterns in the first direction.

18. The elastic member of claim 17, wherein a distance between the plurality of first patterns in the first direction is smaller than a distance between the plurality of second patterns in the first direction.

19. A folding support comprising:
the elastic member of claim 1; and
a protective layer disposed under the elastic member.

20. A display device comprising:
the elastic member of claim 1;
a protective layer under the elastic member;
an adhesive layer on the elastic member; and
a panel layer on the adhesive layer,
wherein the panel layer including at least one of a display panel and a touch panel.
